(19) United States
(12) Patent Application Publication
(10) Pub. No.: US 2020/0127177 A1
(43) Pub. Date: Apr. 23, 2020

(54) Method for Producing an Optoelectronic Component, and Optoelectronic Component

(71) Applicant: OSRAM Opto Semiconductors GmbH, Regensburg (DE)

(72) Inventor: Rainer Bradl, Regensburg (DE)

(21) Appl. No.: 16/620,830

(22) PCT Filed: Jun. 12, 2018
(86) PCT No.: PCT/EP2018/065523

§ 371 Date: Dec. 9, 2019

(30) Foreign Application Priority Data
Jun. 19, 2017 (DE) 10 2017 113 388.7

(51) Int. Cl. H01L 33/60; H01L 33/00; H01L 33/50; H01L 33/54; H01L 33/56

(52) U.S. Cl. CPC H01L 33/60; H01L 33/0079; H01L 33/502; H01L 2933/0058; H01L 33/56; H01L 2933/0041; H01L 2933/005; H01L 33/54

(57) ABSTRACT

The invention concerns a method for producing an optoelectronic component (100) comprising the steps:
A) providing a carrier (1),
B) applying an adhesive (2) on the carrier (1),
C) applying a radiation-emitting semiconductor chip (3) having a main radiation surface (31) and side surfaces (32) on the carrier (1) so that the adhesive (2) covers the main radiation surface (31) and the side surfaces (32) of the semiconductor chip (3) at least predominantly and obliquely,
D) applying a reflector layer (5) at least on an outer adhesive surface (21), which are arranged obliquely to the side surfaces (32) of the semiconductor chip (3),
wherein the carrier (1) is removed again after step C), if applicable.

This patent application is a national phase filing under section 371 of PCT/EP2018/065523, filed Jun. 12, 2018, which claims the priority of German patent application 102017113388.7, filed Jun. 19, 2017, each of which is incorporated herein by reference in its entirety.

### TECHNICAL FILED

The invention concerns a method for producing an optoelectronic component. Furthermore, the invention concerns an optoelectronic component.

### SUMMARY OF THE INVENTION

Embodiments provide a method for producing an optoelectronic component, where the component has improved light extraction. Further embodiments provide an optoelectronic component with improved light extraction compared to conventional components.

In at least one embodiment, the method for producing an optoelectronic component comprises the steps:

A) providing a carrier,

B) applying an adhesive on the carrier,

C) applying a radiation-emitting semiconductor chip having a main radiation surface and side surfaces on the carrier so that the adhesive covers the main radiation surface and the side surfaces of the semiconductor chip at least predominantly and obliquely,

D) applying a reflector layer at least on an outer adhesive surface arranged obliquely to the side surfaces of the semiconductor chip, wherein the carrier is removed again after step C), if applicable.

The invention also concerns an optoelectronic component, which is obtainable from the method described here with the embodiments described here. In this case, all embodiments and definitions of the method for producing an optoelectronic component preferably also apply to the optoelectronic component and vice versa.

According to at least one embodiment, the method has a step A), providing a carrier. For example, the carrier can have one or more materials in the form of a layer, plate, foil or laminate selected from glass, quartz, plastic, metal, stainless steel, Printed Circuit Board (PCB), silicon wafer. In particular, the carrier comprises or consists of glass, a stainless steel plate or PCB.

The carrier is preferably formed temporary. In other words, the carrier is removed again in a later method step, preferably after step C), so that the carrier is not part of the finished optoelectronic component.

According to at least one embodiment, the method has a step B), application of an adhesive on the carrier.

The fact that a layer or element is arranged or applied “on” or “over” another layer or another element can mean here and in the following that the one layer or the one element is arranged or applied directly in mechanical and/or electrical contact with the other layer or the other element. Furthermore, it can also mean that the one layer or the one element is arranged indirectly or over the other layer or the other element. Further layers and/or elements can then be arranged between the one and the other layer or between the one and the other element.

According to at least one embodiment, the adhesive is an inorganic and/or organic adhesive. In particular, the adhesive is a silicone, such as dimethylsiloxane, arylalkylsiloxane or diarylsiloxane. Preferably the adhesive is silicone and does not have any scattering particles. In other words, the adhesive is free of scattering particles or filler materials. The scattering particles or filler materials can be, for example, aluminum oxide, aluminum nitride, titanium dioxide, silicon dioxide, zirconium dioxide, other ceramic as well as vitreous particles, metal oxides or other inorganic particles.

Alternatively, the adhesive can also be an epoxy resin.

According to at least one embodiment, the method comprises a step C), applying a radiation-emitting semiconductor chip having a main radiation surface and side surfaces on the carrier so that the adhesive covers the main radiation side. Alternatively or additionally, the adhesive covers the side surfaces of the semiconductor chip at least predominantly and/or obliquely.

“At least predominantly’ can mean here and in the following that in particular the side surfaces are covered to a proportion of at least 50%, 60%, 70%, 80%, 90%, 95% or 100% by the adhesive.

“Obliquely covered” can mean here that the adhesive seen in the side cross-section forms an outer adhesive surface, which is arranged with respect to the side surfaces obliquely, so there is an angle between the side surfaces and the outer adhesive surface, so that the adhesive has at least regionally an oblique configuration. Preferably, the adhesive, which is arranged on the side surfaces of the semiconductor chips as seen from the side cross-section, has an approximately triangular shape.

The semiconductor chip has at least one semiconductor layer sequence. The semiconductor layer sequence is preferably a III-V compound semiconductor material. The semiconductor material can preferably be based on a nitride compound semiconductor material. “Based on a nitride compound semiconductor material” in the present context means that the semiconductor layer sequence or at least one layer thereof comprises a III-nitride compound semiconductor material, preferably InₓAl_{y}Ga_{1-x-y}N, wherein 0≤x≤1, 0≤y≤1 and x+y≤1. This material does not necessarily have to have a mathematically exact composition according to the above formula. Rather, it can contain one or more dopants and additional components, which essentially do not alter the characteristic physical properties of the InₓAl_{y}Ga_{1-x-y}N material. For simplicity's sake, however, the above formula contains only the essential components of the crystal lattice (In, Al, Ga, N), even if these can be partially replaced by small amounts of other substances.

The optoelectronic component comprises an active layer with at least one pn-junction and/or with one or more quantum well structures. During operation of the optoelectronic component, electromagnetic radiation is generated in the active layer. A wavelength or wavelength maximum of the radiation is preferably in the ultraviolet and/or visible range, in particular at wavelengths between 420 nm and 680 nm inclusive, for example, between 440 nm and 480 nm inclusive.

According to at least one embodiment, the optoelectronic component is a light-emitting diode, LED for short. The component is then preferably configured to emit blue, red or green light or, in combination with a conversion layer, white light.

The semiconductor chip in each case has a main radiation surface. The main radiation surface is preferably arranged perpendicular to the growth direction of the semiconductor layer sequence. The main radiation surface is applied in particular on the carrier in step B). In other words, the main radiation surface of the respective semiconductor chip is arranged directly or indirectly downstream of the carrier. Indirect means here in particular that, for example, an adhesive is arranged between the carrier and the main radiation surface. Directly means here that no further layers or elements are arranged between the carrier and the main radiation surface.

According to at least one embodiment, a plurality of semiconductor chips is arranged on the carrier. In particular, the semiconductor chips are arranged in matrix, preferably as an array, on the carrier. The semiconductor chips are preferably arranged on the carrier in such a way that they are laterally spaced apart in cross-section. The semiconductor chips are in particular configured to preferably emit radiation from the visible range.

According to at least one embodiment, the semiconductor chip or the respective semiconductor chip has contact structures. In particular, the contact structures are a p-contact for contacting the at least one p-doped semiconductor layer and an n-contact for contacting the at least one n-doped semiconductor layer of the semiconductor chip. In particular, the contact structures are both arranged on the side opposite the main radiation surface, that is to say the mounting surface.

The side surfaces are preferably arranged perpendicular to the main radiation surface. If the semiconductor chip is formed as a cuboid, the semiconductor chip has at least four side surfaces, one main radiation surface and the mounting surface opposite the main radiation surface.

According to at least one embodiment, the method has a step D), application of a reflector layer at least on the outer adhesive side. The outer adhesive side is arranged at in particular obliquely to the side surfaces of the semiconductor chip.

According to at least one embodiment, the carrier is removed again after step C).

According to at least one embodiment, the adhesive completely covers the main radiation side and the side surfaces of the semiconductor chip.

According to at least one embodiment, the reflector layer is additionally arranged at least regionally on the mounting surface of the semiconductor chip. The reflector layer surrounds the semiconductor chip frame-like or bowl-like seen from in the side cross-section. In other words, the reflector layer covers both the side surfaces of the semiconductor chip and the mounting underside with the exception of the regions covered by the contact structures of the semiconductor chip. Preferably, the reflector layer is applied in such a way that a short circuit is avoided.

The reflector layer can be formed from an insulating material. The material can be inorganic. Alternatively or additionally, the material can also be formed reflective. The reflector layer can also be a dielectric mirror made of aluminum, for example. In principle, however, all other metals or materials, which are capable of reflecting the light emitted by the semiconductor chip and thus coupling it out of the component efficiently, are also suitable. For example, the reflector layer can be formed from silver.

According to at least one embodiment, in or after step C), the adhesive laterally projects beyond the side surfaces of the semiconductor chip as seen in the side cross-section by a maximum of wo nm to 1 μm, 10 μm, 20 μm, 30 μm, 40 μm, 50 μm, 60 μm, 70 μm, 80 μm, 90 μm or 100 μm as seen in the side cross section.

By providing a carrier and applying an adhesive, preferably in excess, on the carrier and subsequently applying the semiconductor chip on the adhesive, the adhesive can cover both the main radiation surface and the side surfaces of the semiconductor chip as a result of surface tension and/or volume displacement and thus surround the semiconductor chip frame-like at the side surfaces and at the main radiation surface. In the subsequent method step, a reflector layer can be applied, which reflects the light emitted by the semiconductor chip during operation and thus increases the light extraction via the main radiation surface.

According to at least one embodiment, the adhesive arranged on the main radiation surface is removed. The removal can be done, for example, by grinding. In particular, the grinding takes place after the production of a housing in order to expose contact pads again.

According to at least one embodiment, the adhesive arranged on the main radiation surface is not removed.

According to at least one embodiment, a housing is produced after step D), which surrounds the reflector layer frame-like.

According to at least one embodiment, the material of the housing is different from the material of the reflector layer.

The reflector layer is therefore preferably not produced with the material of the housing or component. The functionalities, i.e., the reflectivity and the housing material, are produced separately from one another and can thus be optimized for the respective purpose.

Here and in the following, reflection means that at least 80%, 90% and 95% of the light emitted by the semiconductor chip is reflected by the reflector layer and is thus coupled out of the component, in particular via the main radiation surface, towards the front.

In the method for producing optoelectronic components, for example, in the case of semiconductor chips that are formed as volume emitters, the inventor has recognized that the optoelectronic component described here can improve the light extraction at the side surfaces in the direction of the main radiation surface. So far, only semiconductor components are known that have oblique structures, so that the light is deflected accordingly. In this case, the conventional components have reflective layers of silicone, which are often filled with scattering particles such as titanium dioxide or silicon dioxide. These filled silicones also form the housing of the component. With this technique, however, the properties of the reflector layer are bound to the material properties of the filler material (silicone and filler material such as titanium dioxide) and are therefore limited. Such components can emit both monochrome (red, blue, green, et cetera) but also white light, so that an additional conversion layer is required.

The highly reflective and age-resistant material used so far, such as silicone and titanium dioxide and, if appropriate, silicon dioxide, is difficult to process and less resilient. Also the adhesion of the material is not very good. In conventional components, the reflector layer is made of the same material as the housing. A compromise must therefore be found between the processability of the material, such as silicone and titanium dioxide, the reflectivity and the other material properties, such as temperature resistance, ageing stability, thermal expansion coefficients, material strength and adhesion.

The inventor has now recognized that the separate configuration of the reflector element makes it possible to dispense with an additional housing. Alternatively, a housing can also be used, wherein the material of the housing is in particular different from the material of the reflector layer. Thus, the layers or the housing can be optimally adapted separately for the respective purpose.

According to at least one embodiment, a conversion layer is applied at least on the main radiation surface after step D). The conversion layer can have converter materials such as phosphors such as YAG, garnets, calcines, orthosilicates or alkaline earth nitrides. These phosphors can be embedded in a matrix material such as silicone. The embedding can be homogeneous or inhomogeneous, i.e., with a concentration gradient.

According to at least one embodiment, the outer adhesive surfaces and the respective side surface have an angle a of less than or equal to 45°, 30°, 25°, 20°, 10°. Alternatively or additionally, the mounting surface of the semiconductor chip and the outer adhesive side have an angle b of less than or equal to 45°, 40°, 35°, 30°, 25°, 20°, 15°, 10°, 5°. If necessary, the angle a and/or b can be generated by further processing steps.

According to at least one embodiment, contact structures are arranged on the mounting surface of the semiconductor chip. Before step D) a masking element is arranged over the contact structures, which is removed again after step D). The masking element is preferably a photoresist mask. Thus, the reflector layer can be applied in a structured manner on the mounting surface and, if necessary, on the outer adhesive surface.

According to at least one embodiment, radiation is generated in the semiconductor chip during operation and reaches the reflector layer via the side surfaces and is reflected there. Thus, a majority of the radiation of the component is coupled out via the main radiation surface. In other words, the radiation substantially leaves the component via the main radiation surface.

According to at least one embodiment, the component is free of a housing. Preferably, the reflector layer then forms the final layer of the component, i.e., surrounds the semiconductor chip frame-like, wherein there is no additional housing, in which the semiconductor chip is embedded.

According to at least one embodiment, the reflector layer is produced by vacuum deposition. As a deposition technique, for example, physical vapour deposition (PVD) or chemical vapour deposition (CVD) can be used. Also a chemical separation from a liquid is also an option.

According to at least one embodiment, the reflector layer is formed from silver. In other words, the reflector layer forms a silver mirror.

According to at least one embodiment, the reflector layer has a layer thickness of 100 nm to 10 μm. In particular, the layer thickness depends on the type of reflector layer. A silver mirror, for example, can have a layer thickness of several 10 μm. An inorganic reflector layer, for example, a sequence of AlN and Al₂O₃, can have a layer thickness of less than 1 μm, for example, 100 nm to 900 nm.

According to at least one embodiment, the adhesive is transparent to the radiation emitted by the semiconductor chip. The adhesive is preferably silicone or has silicone, wherein the adhesive is free of scattering particles.

According to at least one embodiment, a plurality of semiconductor chips is applied on the carrier in step C). The semiconductor chips are preferably formed as an array in form of a matrix.

In order to produce the geometric form of the reflector layer, for example, silicone without filler materials is produced around the semiconductor chip with a transparent adhesive. This reflector layer is preferably produced due to the formation of the meniscus, due to the surface tension of the adhesive layer.

Subsequently, the reflector layer can be applied as an independent layer or element by means of CVD or PVD and, if necessary, with the aid of mask techniques. As a result, the reflector layer can be adapted to the given requirements. If the reflector layer is formed from a conductive material, additional masking of the component can be necessary, for example, to prevent short circuits between the contact structures by the conductive reflector layer. The mask technique can also be necessary with non-conductive reflectors, as these otherwise insulate the contact pads.

According to at least one embodiment, an adhesion promoter is applied. The adhesion promoter can improve the adhesion of the reflector layer to the housing material.

The method described here can be carried out both in the front-offline and in the end-offline process.

Since the reflector layer is applied as an independent layer, the housing material can also be applied separately and the material can be selected or adapted according to the requirements. However, there is also the possibility that the housing is completely omitted. In the case that additional housing material is applied, the adhesion between the reflector layer and the housing can be optimized by an adhesion promoter layer or further adhesion promoters.

The inventor has recognized that the method described here can be used to adapt and optimize the reflector layer to the respective requirements. In addition, the housing material can be adapted and optimized to the requirements and processability of the reflector layer independently of the requirements. It is also possible that the component does not have a housing.

### BRIEF DESCRIPTION OF THE DRAWINGS

Further advantages, advantageous embodiments and further modifications result from the exemplary embodiments described in the following in connection with the Figures. They show:

FIGS. 1A to 1E and FIGS. 5A to 5D show methods for producing an optoelectronic component;

FIGS. 2A to 2D and 3A to 3C show schematic side views of optoelectronic components according to embodiments; and

FIGS. 4A and 4B each show a schematic side view of an optoelectronic component according to a comparative example.

### DETAILED DESCRIPTION OF ILLUSTRATIVE EMBODIMENTS

In the exemplary embodiments and in the Figures, identical, similar or similarly acting elements can each be provided with the same reference signs. The shown elements and their proportions are not to be regarded as true to scale. Rather, individual elements, such as layers, devices, components and regions, can be displayed exaggeratedly large for better representability and/or better understanding.

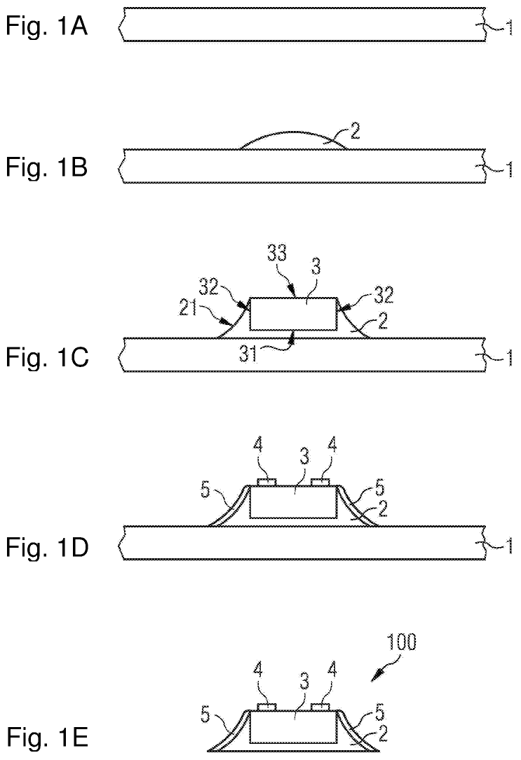

FIGS. 1A to 1E show a method for producing an optoelectronic component according to an embodiment.

As shown in FIG. 1A, a carrier 1 is provided. The carrier can be formed from glass, stainless steel or as a printed circuit board.

An adhesive 2 is applied on the carrier (FIG. 1B). The adhesive 2, for example, can be formed from silicone without filling and/or gritting particles.

At least one semiconductor chip 3 is applied on the adhesive 2 and/or carrier 1 (FIG. 1C). The main radiation surface 31 is immersed in the adhesive 2 or arranged on the adhesive 2. As a result of surface tensions, the side surfaces 32 of the semiconductor chip 3 are also covered by the adhesive.

Preferably the main radiation surface 31 and the side surfaces 32 are completely covered by the adhesive. A slant, i.e., an outer adhesive side 21, forms on the side surfaces 32. As shown in FIG. 1D, the reflector layer 5 can be applied on the outer adhesive side 21. The reflector layer 5, for example, can have a layer thickness of 100 nm. The reflector layer 5 can be made of silver.

Then, as shown in FIG. 1E, the carrier 1 can optionally be removed again. In particular, the carrier 1 is removed so that individual LED components are produced.

The result is an optoelectronic component 100 with a semiconductor chip 3, which is covered by the adhesive 2 on its side surfaces 32 and on the main radiation surface 31. In addition, the component 100 has an obliquely shaped outer adhesive side 21, which is covered by the reflector layer 5 . The component 100 can additionally have contact structures 4, which are used to contact the semiconductor layer sequence of the semiconductor chip 3.

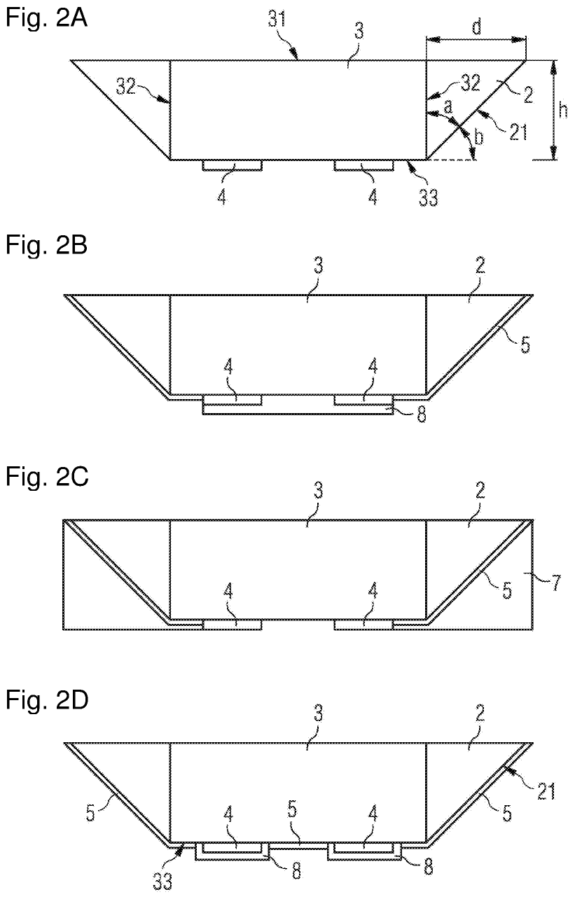

FIG. 2A shows a schematic side view of an optoelectronic component according to an embodiment. The semiconductor chip 3 has the adhesive 2 on its side surfaces 32. Here the adhesive is formed triangular. The adhesive 32 preferably projects beyond the side edges of the chip with a distance d of approximately 100 μm. In particular, the distance d corresponds approximately to the height h of the semiconductor chip.

The adhesive 2 is preferably formed transparent. The outer adhesive side 21 and the respective side surface 32 have an angle a of less than or equal to 45°. Alternatively or additionally, the mounting surface 33 of the semiconductor chip 3 and the outer adhesive surface 21 have an angle b of less than or equal to 45° or greater than or equal to 45°. The angles a and b add up to 90°.

FIG. 2B shows a schematic side view of a component according to an embodiment. The component 100 has a masking element 8, preferably a photoresist mask. After applying the masking element 8, the reflector layer 5 can be applied. In a subsequent method step, the masking element 8 can be removed again. The result is a structured reflector layer 5, which is applied on the mounting side surface 33 in a structured manner. In particular, a conductive reflector layer 5 is spaced from the contact structures 4 to avoid a short circuit.

FIG. 2C shows the schematic side view of an optoelectronic component according to an embodiment, which in addition has a housing 7. The housing 7 and the reflector layer 5 were produced separately and preferably with different materials. Therefore, both the reflector layer 5 and the housing 7 can be optimally adapted to the different purposes or requirements.

FIG. 2D shows a schematic side view of an optoelectronic component boo according to an embodiment. In this schematic side view, the masking is performed with a photoresist mask 8 over the contact structures 4. Subsequently, the reflector element 5 can be applied and thus covers both the outer adhesive surface 21 and the mounting surface 33 of the semiconductor chip 3 cohesively and in a form-fit manner. If the resist mask 8 is formed around the contact structures, there can be a gap between the reflector edge and the pad edge. If this is not desired, the photoresist mask 8 can only be arranged on the pad.

The masking element 8 can be removed again in a subsequent method step. The result is a component that has a reflector layer 5, which surrounds the semiconductor layer frame-like and additionally avoids short circuits in the case of a conductive reflector element.

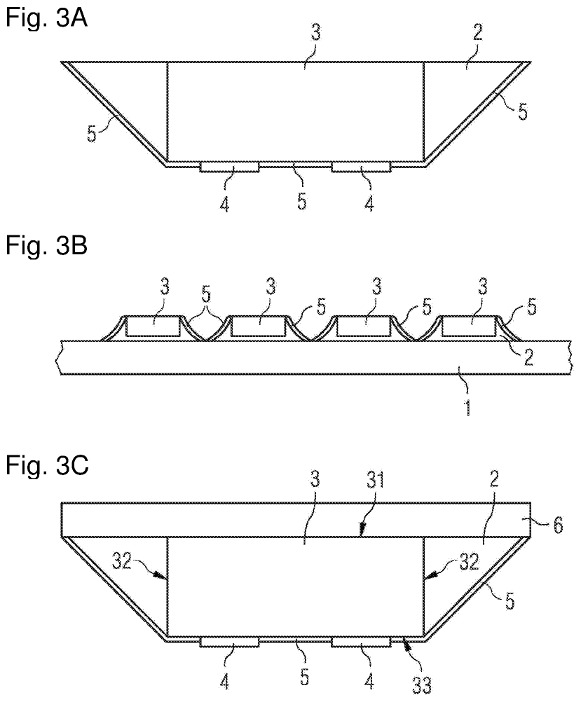

FIG. 3A shows a schematic side view of an optoelectronic component according to an embodiment. Here a finished component 100 is shown, which is free of a housing 7. In other words, the reflector layer 5 forms the final element of the optoelectronic component. With regard to the other elements or layers of the component, reference is made to the preceding explanations of the Figures.

FIG. 3B shows a schematic side view of a method step according to an embodiment. This example shows the application of a plurality of semiconductor chips 3 on a carrier 1. The respective semiconductor chip 3 has an adhesive 2 arranged between the carrier 1 and the semiconductor chip 3 and a respective reflector layer 5, which surrounds the side surfaces of the respective semiconductor chip 3, preferably frame-like. The reflector layer 5 is preferably arranged cohesively and in a form-fit manner on the adhesive 2.

The carrier 1 can be removed again in a final method step, so that a plurality of semiconductor chips can be produced with the embodiment described here.

FIG. 3C shows a schematic side view of an optoelectronic component according to an embodiment. The component of FIG. 3C differs from the component of FIG. 3A in that the component also has a conversion layer 6. The conversion layer is preferably arranged directly downstream of the main radiation surface 31. In particular, the conversion layer 6 is also arranged directly downstream of the adhesive 2. The conversion layer 6 is configured to completely or partially convert the radiation emitted by the semiconductor chip into radiation with a changed, usually longer wavelength. White light, for example, can emerge from the component.

The semiconductor chip 3 can be formed as a volume emitter in all embodiments.

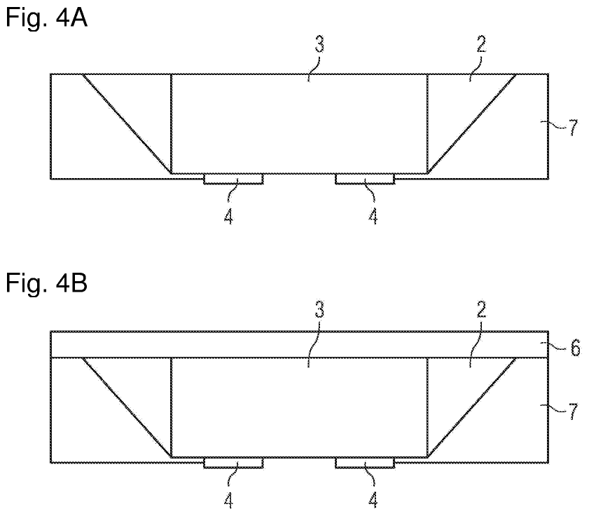

FIG. 4A shows a schematic side view of an optoelectronic component according to a comparative example. The semiconductor chip 3 is preferably formed as a volume emitter and has contact structures 4. The semiconductor chip 3 can be arranged in a housing 7. An adhesive 2 can be arranged between the housing 7 and the side surfaces of the semiconductor chip 3. In comparison to the method described here, this component does not have a reflector layer 5, which can be selected independently of the material of the housing 7.

FIG. 4B shows a schematic side view of a component 100 according to a comparative example. In comparison to the component of Figure 4A, the component of FIG. 4B differs in that it also has a conversion layer 6. The conversion layer 6 is arranged directly downstream of the main radiation surface 31. For example, the semiconductor chip 3 can emit blue light, wherein the phosphors of the conversion layer 6 can convert the blue-emitting light into green or red light. The total light emerged from the component can be white, green, blue or red, for example.

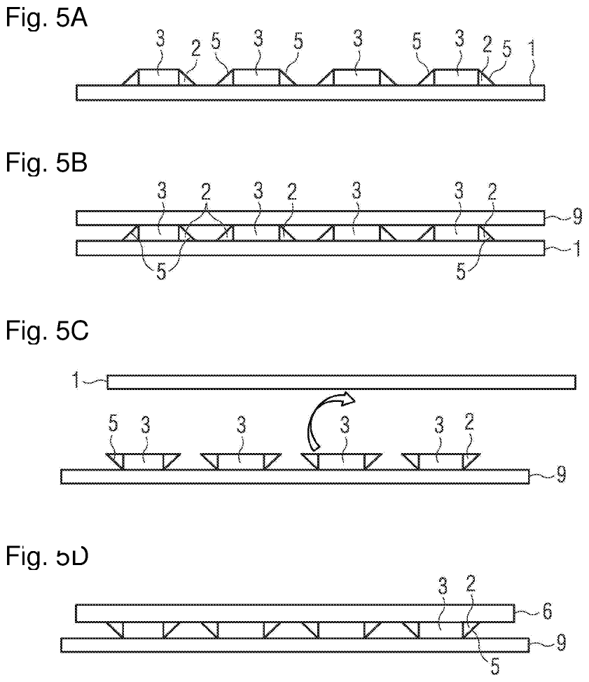

FIGS. 5A to 5D show a method for producing an optoelectronic component according to an embodiment.

FIG. 5A substantially corresponds to the embodiment of FIG. 3B. A schematic side view of a method step according to an embodiment is shown. In this example a carrier 1 is shown on which a plurality of semiconductor chips 3 is arranged. The respective semiconductor chip 3 has an adhesive 2 arranged between the carrier 1 and the semiconductor chip 3 and a respective reflector layer 5, which preferably surrounds or surround the side surfaces of the respective semiconductor chip 3 frame-like. The reflector layer 5 is preferably arranged cohesively and in a form-fit manner on the adhesive 2. Thus, FIG. 5A shows a carrier with LED arrays, which have a reflector layer 5.

As shown in FIG. 5B, a further carrier 9 is applied on the LED arrays. The same materials as described for carrier 1 can be used as a further carrier 9. The further carrier 9 is applied to the back side of the LED arrays.

Subsequently, the carrier 1 can be removed from the front side of the LED arrays as shown in FIG. 5C.

Subsequently, as shown in FIG. 5D, the front side of the LED arrays can be coated with a conversion element 6. Preferably the total number of LEDs or optoelectronic components is coated with a conversion element or a conversion layer.

The step according to FIG. 5D can be optional. Subsequently, the further carrier 9 can optionally be removed again or left in the component. The LED arrays can then be separated to produce a plurality of optoelectronic components.

The exemplary embodiments described in connection with the Figures and their features can also be combined with each other according to further exemplary embodiments, even if such combinations are not explicitly shown in the Figures. Furthermore, the exemplary embodiments described in connection with the Figures can have additional or alternative features as described in general part of the specification.

This patent application claims the priority of the German patent application 10 2017 113 388.7, the disclosure content of which is hereby incorporated by reference.

The invention is not limited by the description based on the exemplary embodiments of these. Rather, the invention includes any new feature and any combination of features, which in particular includes any combination of features in the claims, even if that feature or combination itself is not explicitly mentioned in the claims or exemplary embodiments.

1-19. (canceled)

20. A method for producing an optoelectronic component, the method comprising:
providing a carrier;
applying an adhesive on the carrier;
applying a radiation-emitting semiconductor chip having a main radiation surface and side surfaces on the carrier so that the adhesive covers the main radiation surface and the side surfaces of the semiconductor chip at least predominantly and obliquely;
removing the carrier after applying the semiconductor chip; and
applying a reflector layer at least on an outer adhesive surface arranged obliquely to the side surfaces of the semiconductor chip,
wherein the reflector layer comprises a metal.

21. The method according to claim 20, wherein the adhesive completely covers the main radiation surface and the side surfaces of the semiconductor chip completely cohesively.

22. The method according to claim 20, wherein the reflector layer is additionally arranged at least regionally on a mounting surface of the semiconductor chip, which is opposite the main radiation surface.

23. The method according to claim 20, wherein the adhesive laterally projects beyond the side surfaces of the semiconductor chip as seen in a side cross-section by a maximum of 100 μm.

24. The method according to claim 20, further comprising removing the adhesive arranged on the main radiation surface.

25. The method according to claim 20, further comprising producing a housing that surrounds the reflector layer frame-like.

26. The method according to claim 25, wherein a material of the housing is different from a material of the reflector layer.

27. The method according to claim 20, further comprising applying a conversion layer at least on the main radiation surface after applying the reflector layer.

28. The method according to claim 20, wherein the adhesive has an outer adhesive surface, wherein the outer adhesive surface and a respective side surface of the semiconductor chip form an angle of less than or equal to 45°, and/or wherein a mounting surface of the semiconductor chip and the outer adhesive surface form an angle of less than or equal to 45°.

29. The method according to claim 20, further comprising:
arranging a masking element at least over contact structures before applying the reflector layer, wherein the contact structures are arranged on a mounting surface; and
removing the masking element applying the reflector layer, wherein the masking element is a photoresist mask.

30. The method according to claim 20, wherein the optoelectronic component is free of a housing.

31. The method according to claim 20, wherein applying the reflector layer comprises producing the reflector layer by vapor deposition.

32. The method according to claim 20, wherein the reflector layer is formed of silver.

33. The method according to claim 20, wherein the reflector layer has a layer thickness of 100 nm to 10 μm.

34. The method according to claim 20, wherein the adhesive is transparent to radiation of semiconductor chip, wherein the adhesive comprises silicone, and wherein the adhesive is free of scattering particles.

35. The method according to claim 20, wherein applying the semiconductor chip comprises applying a plurality of semiconductor chips on the carrier.

36. An optoelectronic component obtained from the method according to claim 20.

37. The optoelectronic component according to claim 36, wherein the semiconductor chip is configured to generate radiation which reaches the reflector layer via the side surfaces and which reflects at the reflector layer so that a majority of the radiation leaves the optoelectronic component via the main radiation surface.
